(19) United States
(12) Patent Application Publication
(10) Pub. No.: US 2008/0240196 A1
(43) Pub. Date: Oct. 2, 2008

(54) Surface emitting laser array, method for manufacturing the same, and semiconductor device

(75) Inventor: Tetsuo Nishida, Suwa-shi (JP)

Correspondence Address: ADVANTEDGE LAW GROUP, LLC, 3301 NORTH UNIVERSITY AVE., SUITE 200, PROVO, UT, 84604, US

(73) Assignee: Seiko Epson Corporation, Tokyo (JP)

(21) Appl. No.: 12/079,538

(22) Filed: Mar. 27, 2008

(30) Foreign Application Priority Data
Apr. 2, 2007 (JP) 2007-096431
Mar. 24, 2008 (JP) 2008-076238

(51) Int. Cl. H01S 5/18; H01L 33/00

(52) U.S. Cl. 372/50.12; 438/34; 257/E33.001

(57) ABSTRACT

A surface emitting laser includes the plurality of surface emitting lasers including a first surface emitting laser, a second surface emitting laser adjacent to the first surface emitting laser, and a third surface emitting laser adjacent to the second surface emitting laser. Each of the plurality of surface emitting lasers is operated by an independent signal with respect to one another and includes a first mirror, an active layer, a second mirror, and a columnar portion composed of at least the first mirror and the active layer. A diameter of the columnar portion of the second surface emitting laser is smaller than a diameter of the columnar portion of the first surface emitting laser, and larger than a diameter of the columnar portion of the third surface emitting laser.

The present application comprises contents of Japanese Patent Application No. 2007-96431 applied on Apr. 2, 2007, and Japanese Patent Application No. 2008-76238 applied on Mar. 24, 2008.

### BACKGROUND OF THE INVENTION

The present invention relates to a surface emitting laser array, a method for manufacturing the same, and a semiconductor device.

In related art, most of semiconductor lasers used for laser printers are with a single beam. However, in order to realize high-speed printing using a plurality of beams, a laser array having semiconductor lasers arranged in one dimension or two dimension comes into use as a light source.

Further, because semiconductor lasers are also used for imaging devices such as projectors, a high power is required to improve luminance. Employing a laser array is regarded as a method for that.

However, in a case of employing a laser array for a laser printer, a projector and the like, an issue of variation in output characteristics between elements may arise. For example, in laser printers, variation in output characteristics of a laser array causes grayscale variation upon printing. As a technique to suppress such variation, for example, Japanese Unexamined Patent Application Publication No. 3-90370 discloses a method for controlling an operation of a semiconductor laser corresponding to a light amount of the semiconductor laser by forming a light detector so as to monitor the light amount.

However, in the method disclosed in Japanese Unexamined Patent Application Publication No. 3-90370, in addition to increasing the number of parts, power consumption increases. Further, the number of man-hour for adjusting an optical axis or the like for the semiconductor laser and the light detector is increased, leading to a decrease of yield.

### SUMMARY

A surface emitting laser array according to a first aspect of the invention includes a plurality of surface emitting lasers aligned on a same substrate. The plurality of surface emitting lasers include a first surface emitting laser, a second surface emitting laser adjacent to the first surface emitting laser, and a third surface emitting laser adjacent to the second surface emitting laser. Each of the plurality of surface emitting lasers is operated by an independent signal with respect to one another and includes a first mirror formed on an upper side of the substrate, an active layer formed on an upper side of the first mirror, a second mirror formed on an upper side of the active layer, and a columnar portion composed of at least the second mirror and the active layer. A diameter of the columnar portion of the second surface emitting laser is smaller than a diameter of the columnar portion of the first surface emitting laser, and larger than a diameter of the columnar portion of the third surface emitting laser.

A surface emitting laser array according to a second aspect of the invention includes a plurality of surface emitting lasers aligned on a same substrate. The plurality of surface emitting lasers include a first surface emitting laser, a second surface emitting laser adjacent to the first surface emitting laser, and a third surface emitting laser adjacent to the second surface emitting laser. Each of the plurality of surface emitting lasers is operated by an independent signal with respect to one another and includes a first mirror formed on an upper side of the substrate, an active layer formed on an upper side of the first mirror, a second mirror formed on an upper side of the active layer, and an insulation region at least formed in a part of a region of the second mirror and including an opening portion opening in a direction perpendicular to a surface of the substrate. A diameter of the opening portion of the second surface emitting laser is smaller than a diameter of the opening portion of the first surface emitting laser, and larger than a diameter of the opening portion of the third surface emitting laser.

A semiconductor device according to a third aspect of the invention includes a substrate, a surface emitting laser array including a plurality of surface emitting lasers formed on the substrate, and a drive circuit formed on the substrate and electrically coupled with the plurality of surface emitting lasers. Each of the plurality of surface emitting lasers is operated by an independent signal with respect to one another and includes a first mirror formed on an upper side of the substrate, an active layer formed on an upper side of the first mirror, a second mirror formed on an upper side of the active layer, and a columnar portion composed of at least the second mirror and the active layer. Diameters of the columnar portions respectively included in the plurality of surface emitting lasers are reduced in size from a predetermined position toward an edge portion on the substrate. The predetermined position is in a position closer to a drive circuit side from a center of a region where only the plurality of surface emitting lasers are formed.

A semiconductor device according to a fourth aspect of the invention includes a substrate, a surface emitting laser array including a plurality of surface emitting lasers formed on the substrate, and a drive circuit formed on the substrate and electrically coupled with the plurality of surface emitting lasers. Each of the plurality of surface emitting lasers is operated by an independent signal with respect to one another and includes a first mirror formed on an upper side of the substrate, an active layer formed on an upper side of the first mirror, a second mirror formed on an upper side of the active layer, and an insulation region at least formed in a part of a region of the second mirror and including an opening portion opening in a direction perpendicular to a surface of the substrate. Diameters of the opening portions of the insulation regions respectively included in the plurality of surface emitting lasers are reduced in size from a predetermined position toward an edge portion on the substrate. The predetermined position is in a position closer to a drive circuit side from a center of a region where only the plurality of surface emitting lasers are formed.

A method for manufacturing a surface emitting laser array including a plurality of surface emitting lasers aligned on a same substrate according to a fifth aspect of the invention includes: (a) forming a semiconductor multilayered film for composing a first mirror, an active layer, and a second mirror from a substrate side on an upper side of the substrate; (b) forming an insulation region having an opening portion by injecting an ion in a predetermined region from an upper side of the semiconductor multilayered film; (c) forming a plurality of electrodes having an opening portion composing a light emitting surface on an upper side of the insulation region; and (d) expanding the insulation region by injecting an ion in an opening portion of the insulation region through the opening portion of the electrode.

### BRIEF DESCRIPTION OF THE SEVERAL VIEWS OF THE DRAWING

FIG. 1 is a sectional view schematically showing a surface emitting laser array according to a first embodiment.

FIG. 2 is a diagram showing distinctive portions of the surface emitting laser array according to the first embodiment.

FIG. 3 is a plan view schematically showing the surface emitting laser array according to the first embodiment.

FIG. 4 is a diagram showing distinctive portions of a surface emitting laser array according to a modification of the first embodiment.

FIG. 5 is a plan view schematically showing the surface emitting laser array according to the modification of the first embodiment.

FIG. 6 is a diagram showing a manufacturing step of the surface emitting laser array according to the first embodiment.

FIG. 7 is a diagram showing a manufacturing step of the surface emitting laser array according to the first embodiment.

FIG. 8 is a diagram showing a manufacturing step of the surface emitting laser array according to the first embodiment.

FIG. 9 is a diagram showing a manufacturing step of the surface emitting laser array according to the first embodiment.

FIG. 10 is a sectional view schematically showing a surface emitting laser array according to a second embodiment.

FIG. 11 is a diagram showing distinctive portions of the surface emitting laser array according to the second embodiment.

FIG. 12 is a plan view schematically showing the surface emitting laser array according to the second embodiment.

FIG. 13 is a diagram showing distinctive portions of a surface emitting laser array according to a modification of the second embodiment.

FIG. 14 is a diagram showing a manufacturing step of the surface emitting laser array according to the second embodiment.

FIG. 15 is a sectional view schematically showing a surface emitting laser array according to a third embodiment.

FIG. 16 is a diagram showing a manufacturing step of the surface emitting laser array according to the third embodiment.

FIG. 17 is a diagram showing a temperature of a surface emitting laser corresponding to a diameter of an opening of an insulation region (ion implantation region).

FIG. 18 is a plan view schematically showing a semiconductor device according to a fourth embodiment.

FIG. 19 is a plan view schematically showing a semiconductor device according to a modification of the fourth embodiment.

### DETAILED DESCRIPTION OF THE EMBODIMENT

The present invention can provide a surface emitting laser array, a method for manufacturing the same, and a semiconductor device that can suppress characteristic variance between elements.

A surface emitting laser array according to an embodiment of the invention includes a plurality of surface emitting lasers aligned on a same substrate. The plurality of surface emitting lasers include a first surface emitting laser, a second surface emitting laser adjacent to the first surface emitting laser, and a third surface emitting laser adjacent to the second surface emitting laser. Each of the plurality of surface emitting lasers is operated by an independent signal with respect to one another and includes a first mirror formed on an upper side of the substrate, an active layer formed on an upper side of the first mirror, a second mirror formed on an upper side of the active layer, and a columnar portion composed of at least the first mirror and the active layer. A diameter of the columnar portion of the second surface emitting laser is smaller than a diameter of the columnar portion of the first surface emitting laser, and larger than a diameter of the columnar portion of the third surface emitting laser.

In the surface emitting laser array described above, the first surface emitting laser, the second surface emitting laser, and the third surface emitting laser can be aligned in a straight line.

In the surface emitting laser array described above, the diameters of the columnar portions respectively included in the plurality of surface emitting lasers can be reduced in size from a center toward an edge portion of a region in which the plurality of surface emitting lasers are formed on the substrate.

In the surface emitting laser array described above, the first surface emitting laser, the second surface emitting laser, and the third surface emitting laser are formed on an upper side of the second mirror and further include an electrode having an opening portion for emitting laser light, and a diameter of the opening portion of the electrode included in the first surface emitting laser can be equal to a diameter of the opening portion of the electrode included in the second surface emitting laser and a diameter of the opening portion of the electrode included in the third surface emitting laser.

A surface emitting laser array according to an embodiment of the invention includes a plurality of surface emitting lasers aligned on a same substrate. The plurality of surface emitting lasers includes a first surface emitting laser, a second surface emitting laser adjacent to the first surface emitting laser, and a third surface emitting laser adjacent to the second surface emitting laser. Each of the plurality of surface emitting lasers is operated by an independent signal with respect to one another and includes a first mirror formed on an upper side of the substrate, an active layer formed on an upper side of the first mirror, a second mirror formed on an upper side of the active layer, and an insulation region at least formed in a part of a region of the second mirror and including an opening portion opening in a direction perpendicular to a surface of the substrate. A diameter of the opening portion of the second surface emitting laser is smaller than a diameter of the opening portion of the first surface emitting laser, and larger than a diameter of the opening portion of the third surface emitting laser.

In the surface emitting laser array described above, the first surface emitting laser, the second surface emitting laser, and the third surface emitting laser can be aligned in a straight line.

In the surface emitting laser array described above, the diameters of the opening portions of the insulation regions respectively included in the plurality of surface emitting lasers can be reduced in size from a center toward an edge portion of a region in which the plurality of surface emitting lasers are formed on the substrate.

In the surface emitting laser array described above, the first surface emitting laser, the second surface emitting laser, and the third surface emitting laser are formed on an upper side of the second mirror and further include an electrode having an opening portion for emitting laser light, and a diameter of the opening portion of the electrode included in the first surface emitting laser can be equal to a diameter of the opening portion of the electrode included in the second surface emitting laser and a diameter of the opening portion of the electrode included in the third surface emitting laser.

In the surface emitting laser array described above, the insulation region can be an oxidized constricting layer formed by oxidizing a part of the second mirror.

In the surface emitting laser array described above, the insulation region can be an ion implantation region formed by injecting an ion to a part of the second mirror.

A semiconductor device according to an embodiment of the invention includes a substrate, a surface emitting laser array including a plurality of surface emitting lasers formed on the substrate, a drive circuit formed on the substrate and electrically coupled with the plurality of surface emitting lasers. Each of the plurality of surface emitting lasers is operated by an independent signal with respect to one another and includes a first mirror formed on an upper side of the substrate, an active layer formed on an upper side of the first mirror, a second mirror formed on an upper side of the active layer, and a columnar portion composed of at least the second mirror and the active layer. Diameters of the columnar portions respectively included in the plurality of surface emitting lasers are reduced in size from a predetermined position toward an edge portion on the substrate. The predetermined position is in a position closer to a drive circuit side from a center of a region where only the plurality of surface emitting lasers are formed.

A semiconductor device according to an embodiment of the invention includes a substrate, a surface emitting laser array including a plurality of surface emitting lasers formed on the substrate, a drive circuit formed on the substrate and electrically coupled with the plurality of surface emitting lasers. Each of the plurality of surface emitting lasers is operated by an independent signal with respect to one another and includes a first mirror formed on an upper side of the substrate, an active layer formed on an upper side of the first mirror, a second mirror formed on an upper side of the active layer, and an insulation region at least formed in a part of a region of the second mirror and including an opening portion opening in a direction perpendicular to a surface of the substrate. Diameters of the opening portions of the insulation regions respectively included in the plurality of surface emitting lasers are reduced in size from a predetermined position toward an edge portion on the substrate. The predetermined position is in a position closer to a drive circuit side from a center of a region where only the plurality of surface emitting lasers are formed.

A method for manufacturing a surface emitting laser array according to an embodiment of the invention is a method for manufacturing a surface emitting laser array including a plurality of surface emitting lasers aligned on a same substrate and includes: (a) forming a semiconductor multilayered film for composing a first mirror, an active layer, and a second mirror from a substrate side on an upper side of the substrate; (b) forming an insulation region having an opening portion by injecting an ion in a predetermined region from an upper side of the semiconductor multilayered film; (c) forming a plurality of electrodes having an opening portion composing a light emitting surface in an upper side of the insulation region; (d) expanding the insulation region by injecting an ion in the opening portion of the insulation region through the opening portion of the electrode.

The method for manufacturing a surface emitting laser array described above further includes measuring a temperature of the semiconductor multilayered film while an electric current is injected to each of the electrodes after step (c), and a region to inject the ion in the semiconductor multilayered film is determined based on the measured temperature, and the ion is injected to the determined region in step (d).

In the method for manufacturing a surface emitting laser array described above, the opening portion of the insulation region formed in step (b) can be formed in an inner side of the opening portion of the electrode.

In the method for manufacturing a surface emitting laser array described above, diameters of the opening portions of the insulation regions can be reduced in size from a center toward an edge portion of a region in which the plurality of surface emitting lasers are formed on the substrate.

Embodiments of the invention will now be described with reference to the accompanying drawings.

### 1. First Embodiment

### 1.1. Surface Emitting Laser Array

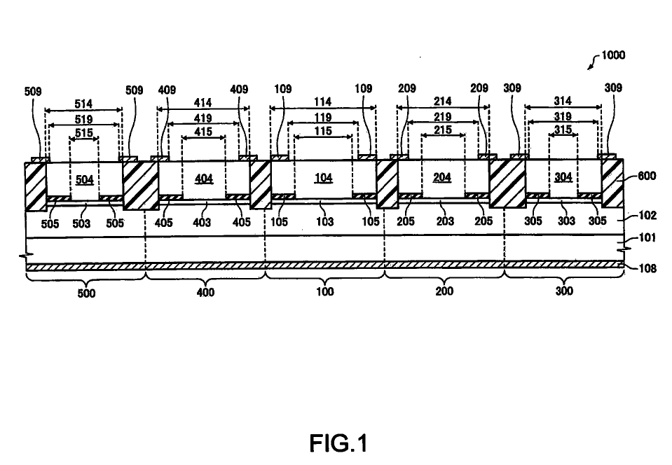

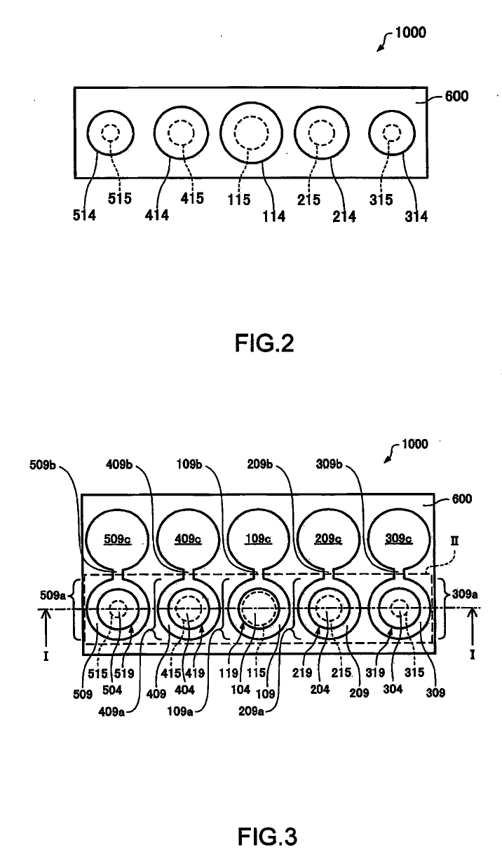

First, a configuration of a surface emitting laser array 1000 according to a first embodiment will be described. FIGS. 1 and 3 are diagrams schematically showing the surface emitting laser array 1000 according to the first embodiment. FIG. 1 is a sectional view schematically showing the surface emitting laser array 1000 according to the first embodiment, while FIG. 3 is a plan view schematically showing the surface emitting laser array 1000 according to the first embodiment. Further, FIG. 2 is a diagram for explaining diameters of columnar portions and openings of oxidized constricting layers of the surface emitting laser array 1000 according to the first embodiment. FIG. 1 is a diagram showing a sectional view taken along a line I to I in FIG. 3, while FIG. 2 is a diagram showing a region II in FIG. 3.

The surface emitting laser array 1000 includes a plurality of surface emitting lasers aligned on a same substrate. In the first embodiment, first, the surface emitting laser array 1000 including five surface emitting lasers (a first surface emitting laser 100, a second surface emitting laser 200, a third surface emitting laser 300, a fourth surface emitting laser 400, and a fifth surface emitting laser 500) aligned in a straight line will be explained.

The surface emitting laser array 1000 includes the first surface emitting laser 100, the second surface emitting laser 200, the third surface emitting laser 300, the fourth surface emitting laser 400, and the fifth surface emitting laser 500. The first surface emitting laser 100 is adjacent to the second surface emitting laser 200 and the fourth surface emitting laser 400. The second surface emitting laser 200 is adjacent to the third surface emitting laser 300, and the fourth surface emitting laser 400 is adjacent to the fifth surface emitting laser 500.

The first surface emitting laser 100, the second surface emitting laser 200, the third surface emitting laser 300, the fourth surface emitting laser 400, and the fifth surface emitting laser 500 are formed on a semiconductor substrate 101, and include a second electrode 108 formed on a lower surface of the semiconductor substrate 101, and a first mirror 102 formed on an upper surface of the semiconductor substrate 101. The second electrode 108 and the first mirror 102 can function as an electrode and a mirror that are common to each of the surface emitting lasers.

In the first surface emitting laser 100, the second surface emitting laser 200, the third surface emitting laser 300, the fourth surface emitting laser 400, and the fifth surface emitting laser 500, diameters of columnar portions (shown in numerals 114, 214, 314, 414, and 514) and diameters of openings of oxidized constricting layers (shown in numerals 115, 215, 315, 415, and 515) are different from each other. Other portions are in the same size and include the same material with respect to one another.

Since each of the first surface emitting laser 100, the second surface emitting laser 200, the third surface emitting laser 300, the fourth surface emitting laser 400, and the fifth surface emitting laser 500 can be operated by an independent signal from each other, each can emit at a different timing with respect to one another. Alternatively, these surface emitting lasers can be operated in a group of plural numbers by a same signal.

A detailed configuration of each of the surface emitting lasers is as follows.

The first surface emitting laser 100 includes the first mirror 102, an active layer 103 formed on the first mirror 102, a second mirror 104 formed on the active layer 103. The first surface emitting laser 100 is provided with a vertical resonator composed of the first mirror 102, the active layer 103, and the second mirror 104. Further, the first mirror 102, the active layer 103, and a part of the second mirror 104 can constitute a semiconductor deposited body (columnar portion) 114 in a pillar shape. The columnar portion 114 can have, for example, a circular cross section when being cut at a surface parallel to the upper surface of the semiconductor 101.

The semiconductor substrate 101 can be made of an n-type GaAs substrate, for example. The first mirror 102 can be made of a distributed reflection type multilayer mirror composed of alternately layered 40 pairs of an n-type Al_{0.9} Ga_{0.1}As layer and an n-type Al_{0.15} Ga_{0.85} As layer, for example. The active layer 103 is composed of a GaAs well layer and an Al_{0.3} Ga_{0.7}As barrier layer, for example, and can include a quantum well structure composed of three well layers. The second mirror 104 can be made of a distributed reflection type multilayer mirror composed of alternately layered 25 pairs of a p-type Al_{0.9} Ga_{0.1}As layer and a p-type Al_{0.15} Ga_{0.85}As layer, for example.

The second mirror 104 is made to be a p-type by doping carbon (C) for example, while the first mirror 102 is made to be an n-type by doping silicon (Si) for example. Therefore, the second mirror 104 of the p-type, the active layer 103 containing no doped impurities, and the first mirror 102 of the n-type constitute a pin diode.

The first surface emitting laser 100 further includes an oxidized constricting layer 105 formed on an upper side of the active layer 103 as an insulating region. Specifically, the oxidized constricting layer 105 is obtained by oxidizing a AlₓGa₁₋ₓAs (x>0.95) layer in a region closer to the active layer 103 among layers composing the second mirror 104 from a side surface. This oxidized constricting layer 105 has the opening 115, and is formed in a ring shape, for example. That is, in the oxidized constricting layer 105, a cross section when being cut at the surface parallel to the upper surface of the semiconductor 101 can be in a ring shape of a concentric circle with respect to a circle in a plane shape of the columnar portion 114.

The first surface emitting laser 100 includes a first electrode 109 formed on an upper side of the second mirror 104. By injecting an electric current to the pin diode using the first electrode 109 and the second electrode 108 described above, the first surface emitting laser 100 can be operated.

The second electrode 108 can be composed of layered films of a gold (Au) and germanium (Ge) alloy, and gold (Au), for example. Further, the first electrode 109 can be composed of layered films of platinum (Pt), titanium (Ti), and gold (Au).

The first electrode 109 can be in a ring shape having an opening 119 at the upper surface of the columnar portion 114. At the opening 119, a cross section when being cut at the surface parallel to the upper surface of the semiconductor substrate 101 can be in a circular shape of a concentric circle with respect to a circle in a plane shape of the columnar portion 114. Further, other than a ring shape portion 109a, the first electrode 109 has a pad portion 109c for electrically coupling with other elements, a lead portion in a linear shape for coupling the pad portion and the ring shape portion 109a (refer to FIG. 3).

A diameter of the opening 119 of the first electrode 109 is, as shown in FIGS. 1 to 3, smaller than the diameter of the columnar portion 114, and larger than the diameter of the opening 115 of the oxidized constricting layer 105. Since the diameter of the opening 119 is larger than the diameter of the opening 115 of the oxidized constricting layer 105, light generated among the first mirror 102, the active layer 103, and the second mirror 104 is prevented from being blocked by a lower surface of the first electrode 109.

The second surface emitting laser 200 includes, similarly to the first surface emitting laser 100, the first mirror 102, an active layer 203 formed on the first mirror 102, a second mirror 204 formed on the active layer 203. The second surface emitting laser 200 is provided with a vertical resonator composed of the first mirror 102, the active layer 203, and the second mirror 204. Further, the first mirror 102, the active layer 203, and a part of the second mirror 204 can constitute a semiconductor deposited body (columnar portion) 214 in a pillar shape. Materials of the active layer 203 and the second mirror 204 can be the same materials as those of the active layer 103 and the second mirror 104 described above. Therefore, the second mirror 204 of a p-type, the active layer 203 containing no doped impurities, and the first mirror 102 of an n-type constitute a pin diode.

The second surface emitting laser 200 further includes an oxidized constricting layer 205 formed on an upper side of the active layer 203. The second surface emitting laser 200 includes a first electrode 209 formed on an upper surface of the second mirror 204. By injecting an electric current to the pin diode using the first electrode 209 and the second electrode 108 described above, the first surface emitting laser 100 can be operated.

Materials of the first electrode 209 and the oxidized constricting layer 205 can be also respectively the same materials as those of the first electrode 109 and the oxidized constricting layer 105.

The first electrode 209 can be in a ring shape having an opening 219 at the upper surface of the columnar portion 214. At the opening 219, a cross section when being cut at the surface parallel to the upper surface of the semiconductor substrate 101 can be in a circular shape of a concentric circle with respect to a circle in a plane shape of the columnar portion 214. Further, other than a ring shape portion 209a, the first electrode 209 has a pad portion 209c for electrically coupling with other elements, a lead portion in a linear shape for coupling the pad portion and the ring shape portion 209a (refer to FIG. 3).

A diameter of the opening 219 of the first electrode 209 is, as shown in FIGS. 1 to 3, smaller than the diameter of the columnar portion 214, and larger than the diameter of the opening 215 of the oxidized constricting layer 205.

The third surface emitting laser 300 includes, similarly to the first surface emitting laser 100, the first mirror 102, an active layer 303 formed on the first mirror 102, a second mirror 304 formed on the active layer 303. The third surface emitting laser 300 is provided with a vertical resonator composed of the first mirror 102, the active layer 303, and the second mirror 304. Further, the first mirror 102, the active layer 303, and a part of the second mirror 304 can constitute a semiconductor deposited body (columnar portion) 314 in a pillar shape. Materials of the active layer 303 and the second mirror 304 can be the same materials as those of the active layer 103 and the second mirror 104 described above. Therefore, the second mirror 304 of a p-type, the active layer 303 containing no doped impurities, and the first mirror 102 of an n-type constitute a pin diode.

The third surface emitting laser 300 further includes an oxidized constricting layer 305 formed on an upper side of the active layer 303. The third surface emitting laser 300 includes a first electrode 309 formed on an upper surface of the second mirror 304. By injecting an electric current to the pin diode using the first electrode 309 and the second electrode 108 described above, the first surface emitting laser 100 can be operated.

Materials of the first electrode 309 and the oxidized constricting layer 305 can be also respectively the same materials as those of the first electrode 109 and the oxidized constricting layer 105.

The first electrode 309 can be in a ring shape having an opening 319 at the upper surface of the columnar portion 314. At the opening 319, a cross section when being cut at the surface parallel to the upper surface of the semiconductor substrate 101 can be in a circular shape of a concentric circle with respect to a circle in a plane shape of the columnar portion 314. Further, other than a ring shape portion 309a, the first electrode 309 has a pad portion 309c for electrically coupling with other elements, a lead portion in a linear shape for coupling the pad portion and the ring shape portion 309a (refer to FIG. 3).

A diameter of the opening 319 of the first electrode 309 is, as shown in FIGS. 1 to 3, smaller than the diameter of the columnar portion 314, and larger than the diameter of the opening 315 of the oxidized constricting layer 305.

The fourth surface emitting laser 400 includes, similarly to the first surface emitting laser 100, the first mirror 102, an active layer 403 formed on the first mirror 102, a second mirror 404 formed on the active layer 403. The fourth surface emitting laser 400 is provided with a vertical resonator composed of the first mirror 102, the active layer 403, and the second mirror 404. Further, the first mirror 102, the active layer 403, and a part of the second mirror 404 can constitute a semiconductor deposited body (columnar portion) 414 in a pillar shape. Materials of the active layer 403 and the second mirror 404 can be the same materials as those of the active layer 103 and the second mirror 104 described above. Therefore, the second mirror 404 of a p-type, the active layer 403 containing no doped impurities, and the first mirror 102 of an n-type constitute a pin diode.

The fourth surface emitting laser 400 further includes an oxidized constricting layer 405 formed on an upper side of the active layer 403. Further, the fourth surface emitting laser 400 includes a first electrode 409 formed on an upper surface of the second mirror 404. By injecting an electric current to the pin diode using the first electrode 409 and the second electrode 108 described above, the first surface emitting laser 100 can be operated.

Materials of the first electrode 409 and the oxidized constricting layer 405 can be also respectively the same materials as those of the first electrode 109 and the oxidized constricting layer 105.

The first electrode 409 can be in a ring shape having an opening 419 at the upper surface of the columnar portion 414. At the opening 419, a cross section when being cut at the surface parallel to the upper surface of the semiconductor substrate 101 can be in a circular shape of a concentric circle with respect to a circle in a plane shape of the columnar portion 414. Further, other than a ring shape portion 409a, the first electrode 409 has a pad portion 409c for electrically coupling with other elements, a lead portion in a linear shape for coupling the pad portion and the ring shape portion 409a (refer to FIG. 3).

A diameter of the opening 419 of the first electrode 409 is, as shown in FIGS. 1 to 3, smaller than the diameter of the columnar portion 414, and larger than the diameter of the opening 415 of the oxidized constricting layer 405.

The fifth surface emitting laser 500 includes, similarly to the first surface emitting laser 100, the first mirror 102, an active layer 503 formed on the first mirror 102, a second mirror 504 formed on the active layer 503. The fifth surface emitting laser 500 is provided with a vertical resonator composed of the first mirror 102, the active layer 503, and the second mirror 504. Further, the first mirror 102, the active layer 503, and a part of the second mirror 504 can constitute a semiconductor deposited body (columnar portion) 514 in a pillar shape. Materials of the active layer 503 and the second mirror 504 can be the same materials as those of the active layer 103 and the second mirror 104 described above. Therefore, the second mirror 504 of a p-type, the active layer 503 containing no doped impurities, and the first mirror 102 of an n-type constitute a pin diode.

The fifth surface emitting laser 500 further includes an oxidized constricting layer 505 formed on an upper side of the active layer 503. The fifth surface emitting laser 500 includes a first electrode 509 formed on an upper surface of the second mirror 504. By injecting an electric current to the pin diode using the first electrode 509 and the second electrode 108 described above, the first surface emitting laser 100 can be operated.

Materials of the first electrode 509 and the oxidized constricting layer 505 can be also respectively the same materials as those of the first electrode 109 and the oxidized constricting layer 105.

The first electrode 509 can be in a ring shape having an opening 519 at the upper surface of the columnar portion 514. At the opening 519, a cross section when being cut at the surface parallel to the upper surface of the semiconductor substrate 101 can be in a circular shape of a concentric circle with respect to a circle in a plane shape of the columnar portion 514. Further, other than a ring shape portion 509a, the first electrode 509 has a pad portion 509c for electrically coupling with other elements, a lead portion in a linear shape for coupling the pad portion and the ring shape portion 509a (refer to FIG. 3).

A diameter of the opening 519 of the first electrode 509 is, as shown in FIGS. 1 to 3, smaller than the diameter of the columnar portion 514, and larger than the diameter of the opening 515 of the oxidized constricting layer 505.

Next, the diameters of the columnar portions 114, 214, 314, 414, and 514 will be explained. The diameters of the columnar portions 114, 214, 314, 414, and 514 are formed to be reduced in size from a center toward edges of a region where the plurality of the surface emitting lasers 100, 200, 300, 400, and 500 (refer to FIG. 2) are formed on the semiconductor substrate 101. That is, among the columnar portions 114, 214, and 314, the diameter of the columnar portion 114 that is formed in the center is the largest, and then the diameters of the columnar portion 214 and the columnar portion 314 are getting smaller in this order. Further, among the columnar portions 114, 414, and 514, the diameter of the columnar portion 114 that is formed in the center is the largest, and then the diameters of the columnar portion 414 and the columnar portion 514 are getting smaller in this order.

According to this, in the surface emitting laser array 1000, optical outputs of the plurality of surface emitting lasers can be equalized by making the diameters of the columnar portions smaller from the center toward the edges. Details are as follows.

If the diameters of the columnar portions of the plurality of surface emitting lasers included in the surface emitting laser array are equalized, the surface emitting laser in the center has a higher temperature compared to the surface emitting lasers in the edges. When the surface emitting laser has a high temperature, an optical output is degraded. Thus, an optical output of the surface emitting laser having the high temperature in the center is particularly degraded.

Therefore, as the surface emitting laser array 1000 according to the embodiment, by making the diameters of the columnar portions smaller from the center toward the edges, temperature differences between the first surface emitting lasers 100, 200, 300, 400, and 500 are made smaller, reducing differences of optical outputs so as to equalize the optical outputs.

The diameter of the columnar potion 214 can be either the same, or different from that of the columnar portion 414. Further, the diameter of the columnar potion 314 can be either the same, or different from that of the columnar portion 514. For example, in a case where other elements are formed on the semiconductor substrate 101, if the other elements are formed on a third surface emitting laser 300 side, it is preferable that the diameter of the columnar portion 214 be larger than that of the columnar portion 414, and the diameter of the columnar portion 314 be larger than that of the columnar portion 514.

On the other hand, if the other elements are formed on a fifth surface emitting laser 500 side, it is preferable that the diameter of the columnar portion 214 be smaller than that of the columnar portion 414, and the diameter of the columnar portion 314 be smaller than that of the columnar portion 514. According to this, the temperatures of the surface emitting lasers 400 and 500 are prevented from partially rising by heat generated from the other elements, maintaining even optical outputs.

Next, the diameters of openings 115, 215, 315, 415, and 515 respectively formed in the oxidized constricting layers 105, 205, 305, 405, and 505 will be explained. The diameters of the openings 115, 215, 315, 415, and 515 are formed to be reduced in size from the center toward the edges of the region where the plurality of surface emitting lasers 100, 200, 300, 400, and 500 (refer to FIG. 2) are formed on the semiconductor substrate 101. That is, among the openings 115, 215, and 315, the diameter of the opening 115 that is formed in the center is the largest, and then the diameters of the opening 215 and the opening 315 are getting smaller in this order. Further, among the openings 115, 415, and 515, the diameter of the opening 115 that is formed in the center is the largest, and then the diameters of the opening 415 and the opening 515 are getting smaller in this order.

According to this, in the surface emitting laser array 1000, optical outputs of the plurality of surface emitting lasers can be equalized by making the diameters of the openings of the oxidized constricting layers smaller from the center toward the edges. Details are as follows.

If the diameters of the openings of the oxidized constricting layers of the plurality of surface emitting lasers included in the surface emitting laser array are equalized, the surface emitting laser in the center has a higher temperature compared to the surface emitting lasers in the edges. When the surface emitting laser has a high temperature, an optical output is degraded. Thus, an optical output of the surface emitting laser having the high temperature in the center is particularly degraded.

Therefore, as the surface emitting laser array 1000 according to the embodiment, by making the diameters of the openings of the oxidized constricting layers smaller from the center toward the edges, temperature differences between the first surface emitting lasers 100, 200, 300, 400, and 500 are made smaller, reducing differences of optical outputs so as to equalize the optical outputs.

The opening 215 can be either the same, or different from the opening 415. Further, the opening 315 can be either the same, or different from the opening 515. For example, in a case where other elements are formed on the semiconductor substrate 101, if the other elements are formed on the third surface emitting laser 300 side, it is preferable that the diameter of the opening 215 of the oxidized constricting layer 205 be larger than that of the opening 415 of the oxidized constricting layer 405, and the diameter of the opening 315 of the oxidized constricting layer 305 be larger than that of the opening 515 of the oxidized constricting layer 505.

On the other hand, if the other elements are formed on the fifth surface emitting laser 500 side, it is preferable that the diameter of the opening 215 of the oxidized constricting layer 205 be smaller than that of the opening 415 of the oxidized constricting layer 405, and the diameter of the opening 315 of the oxidized constricting layer 305 be smaller than that of the opening 515 of the oxidized constricting layer 505. According to this, the temperatures of the surface emitting lasers 400 and 500 are prevented from partially rising by heat generated from the other elements, maintaining even optical outputs.

The diameters of the openings 119, 219, 319, 419, and 519 respectively formed in the first electrodes 109, 209, 309, 409, and 509 are preferably equal to each other. By equalizing the diameters of the openings 119, 219, 319, 419, and 519, beam diameters can be equalized.

### 1.2.2. Two Dimensional Surface Emitting Laser Array

Until now, the surface emitting laser array 1000 provided with the plurality of surface emitting lasers arranged in a single dimension has been described. However, a surface emitting laser array 1500 provided with a plurality of surface emitting lasers arranged in a two dimension can also have the same features as those of the surface emitting laser array 1000 provided with the plurality of surface emitting lasers arranged in a single dimension. Details are as follows.

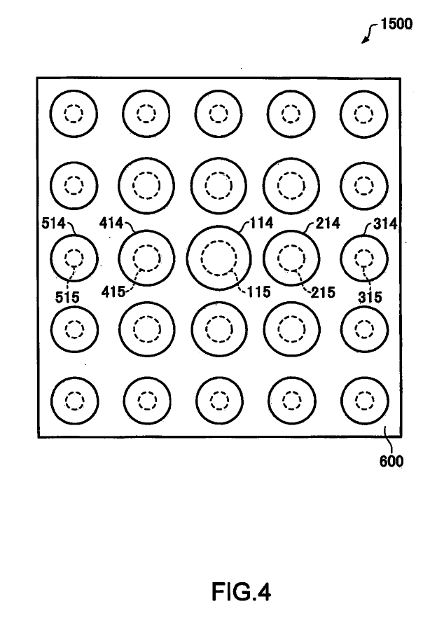

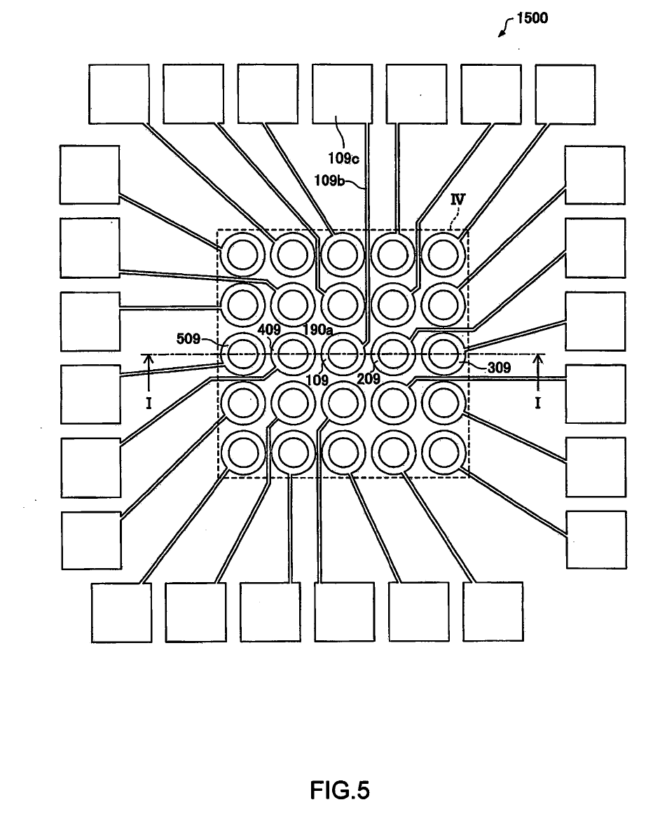

FIGS. 4 and 5 are diagrams schematically showing the surface emitting laser array 1500 according to a modification of the first embodiment. FIG. 5 is a plan view schematically showing the surface emitting laser array 1500 according to the modification. FIG. 4 is a diagram for explaining diameters of columnar portions and openings of oxidized constricting layers of the surface emitting laser array 1500 according to the modification. Note that FIG. 4 is a diagram showing a region IV in FIG. 5.

As shown in FIGS. 4 and 5, the surface emitting laser array 1500 includes 25 pieces of surface emitting lasers arranged in five rows and five columns. Among these surface emitting lasers, for example, five surface emitting lasers in the third row can have the same configuration and features as those of the first surface emitting laser 100, the second surface emitting laser 200, the third surface emitting laser 300, the fourth surface emitting laser 400, and the fifth surface emitting laser 500. Five surface emitting lasers formed in the third column or in a diagonal line can also have the same configuration and features as those of the first surface emitting laser 100, the second surface emitting laser 200, the third surface emitting laser 300, the fourth surface emitting laser 400, and the fifth surface emitting laser 500.

That is, as shown in FIGS. 4 and 5, the surface emitting laser array 1500 can also have columnar portions having diameters made to be reduced in size radially from a center toward edges of the surface emitting laser array (forming region). In this way, temperature differences between the plurality of surface emitting lasers, and further, optical outputs of the plurality of surface emitting lasers can be equalized.

Further, in the surface emitting laser array 1500, diameters of openings of oxidized constricting layers are reduced in size from the center toward the edges. In this way, temperature differences between the plurality of surface emitting lasers, and further, optical outputs of the plurality of surface emitting lasers can be equalized.

In addition, in the surface emitting laser array 1500, the first electrode (denoted by the numeral 109, and the like) included in each of the surface emitting lasers is preferably formed so that a pad portion (denoted by the numeral 109c, and the like) and a lead portion (denoted by a numeral 109b, and the like) are formed in a shape of point symmetry about the first electrode of a central surface emitting laser as a center. In this way, disproportionate temperature distribution of the surface emitting laser array 1500 can be prevented.

### 1.3. Method for Manufacturing a Surface Emitting Laser Array

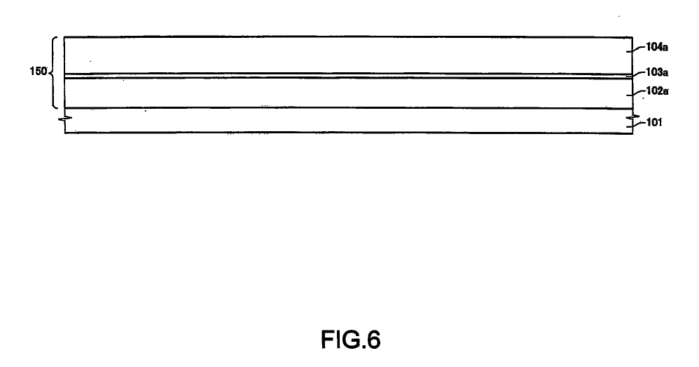

Next, an example of a method for manufacturing the surface emitting laser array 1000 according to the embodiment employing the invention will be explained with reference to FIGS. 6 through 9. FIGS. 6 through 9 are sectional views schematically showing a manufacturing steps of the surface emitting laser arrays 1000 and 1500 shown in FIGS. 1 to 5, and each corresponds to the sectional view shown in FIG. 1.

(1) First, a semiconductor multilayered film 150 is formed on an upper surface of the semiconductor substrate 101 composed of an n-type GaAs layer by epitaxial growth while varying a composition as shown in FIG. 6. Here, the semiconductor multilayered film 150 is, for example, composed of a first mirror 102a composed of alternately layered 40 pairs of an n-type Al_{0.9} Ga_{0.1}As layer and an n-type Al_{0.15}Ga_{0.85} As layer, an active layer 103a composed of a GaAs well layer and a Al_{0.3}Ga_{0.7}As barrier layer and including a quantum well structure composed of three well layers, and a second mirror 104a composed of alternately layered 25 pairs of a p-type Al_{0.9} Ga_{0.1}As layer and a p-type Al_{0.15} Ga_{0.85}As layer. The semiconductor multilayered film 150 is formed by layering these layers in order on the semiconductor substrate 101.

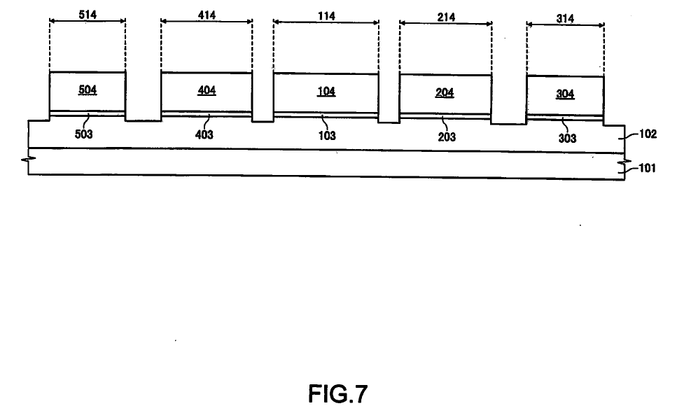

(2) Next, the semiconductor multilayered film 150 is patterned by known photolithography and etching techniques. According to this, the columnar portions 114, 214, 314, 414, and 514 are formed as shown in FIG. 7.

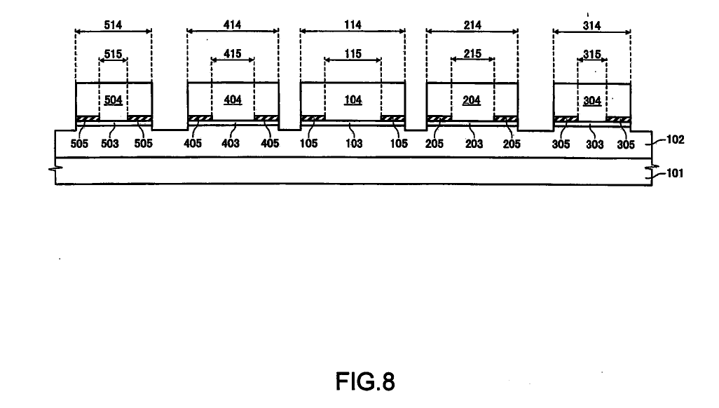

(3) Next, for example, by loading the semiconductor substrate 101 into a steam atmosphere at a temperature of about 400 degrees Celsius, a layer having a high Al composition in the second mirror of the columnar portions 114, 214, 314, 414, and 514 is oxidized from a side surface, forming the oxidized constricting layers 105, 205, 305, 405, and 505 (refer to FIG. 8).

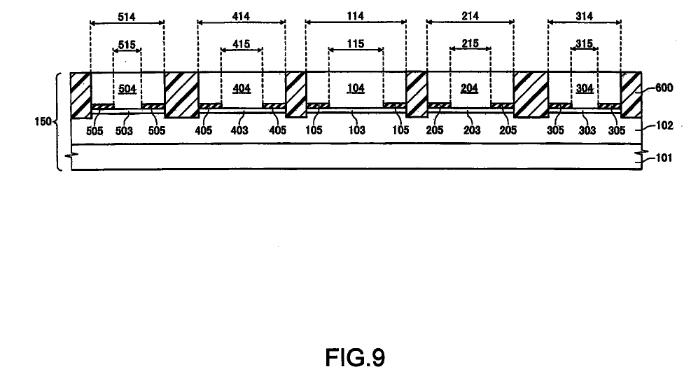

(4) Next, as shown in FIG. 9, an insulation layer 600 is formed. As the insulation layer 600, for example, something obtained by curing a liquid material that is curable by energy such as heat, light, or the like (a precursor of ultraviolet-curing resin or thermosetting resin, for example) can be employed. As the ultraviolet curable resin, for example, acrylic base resin and epoxy base resin of an ultraviolet curable type can be listed. Further, as the thermosetting resin, polyimide base resin of a thermosetting type can be exemplified. Furthermore, as the insulation layer 600, for example, an inorganic type dielectric film such as a silicon oxide film, a silicon nitride film, or the like can be used. In addition, the insulation layer 600 can also be a layered film formed by using a plurality of the materials described above, for example.

(5) Next, by a known method such as a vacuum vapor deposition method or the like, the first electrode 109 and the second electrode 108 are formed (refer to FIG. 1). First, before forming the first electrode 109, a top surface of the second mirror 104 is cleaned by plasma treatment or the like as needed. According to this, an element having more stable characteristics can be formed.

Subsequently, for example, a gold film is formed by the vacuum vapor deposition method. Subsequently, by removing the layered film other than a predetermined region by a lift-off method, the first electrode 109 is formed. Then, the second electrode 108 is formed in the same way.

According to the steps above, as shown in FIGS. 1 through 5, the surface emitting laser array 1000 or the surface emitting laser array 1500 is obtained.

### 2. Second Embodiment

### 2.1. Surface Emitting Laser Array

A surface emitting laser array 2000 according to a second embodiment differs from the surface emitting laser array 1000 described above in that an oxidized constricting layer is not included, but an ion implantation region is included, and diameters of columnar portions are the same with each other among a plurality of surface emitting lasers.

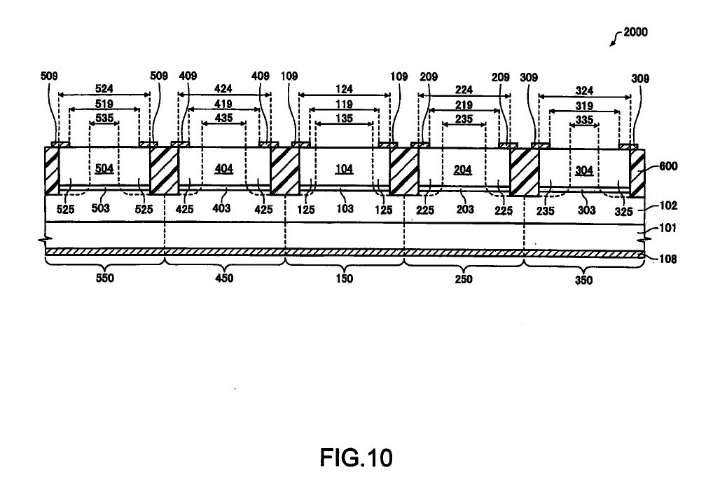

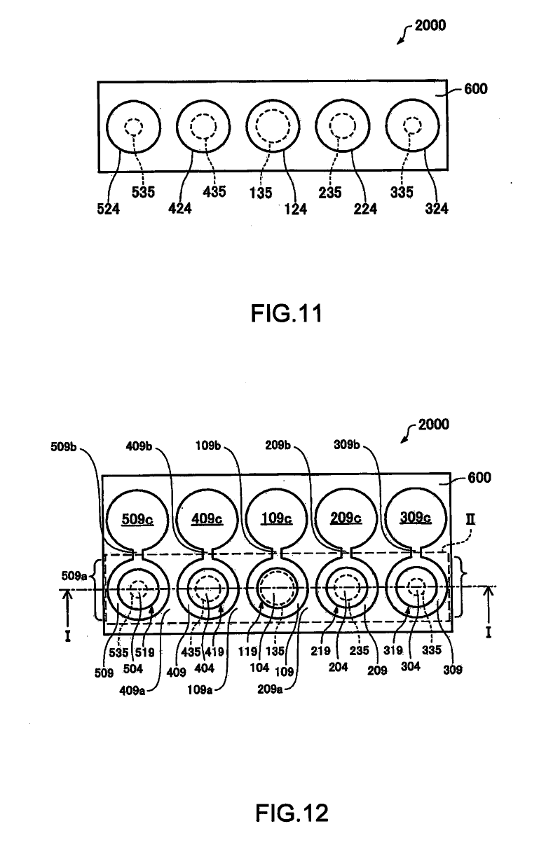

A configuration of the surface emitting laser array 2000 according to the second embodiment will be described. FIGS. 10 and 12 are diagrams schematically showing the surface emitting laser array 2000 according to the second embodiment. FIG. 10 is a sectional view schematically showing the surface emitting laser array 2000 according to the second embodiment, while FIG. 12 is a plan view schematically showing the surface emitting laser array 2000 according to the second embodiment. Further, FIG. 11 is a diagram for explaining diameters of columnar portions and openings of ion implantation regions of the surface emitting laser array 2000 according to the second embodiment. Note that FIG. 10 is a diagram showing a sectional view taken along a line I-I in FIG. 12, while FIG. 11 is a diagram showing a region II in FIG. 12.

The surface emitting laser array 2000 includes a plurality of surface emitting lasers aligned on a same substrate similarly to the surface emitting laser array 1000 described above. In the second embodiment, the surface emitting laser array 2000 including five surface emitting lasers (a first surface emitting laser 150, a second surface emitting laser 250, a third surface emitting laser 350, a fourth surface emitting laser 450, and a fifth surface emitting laser 550) aligned in a straight line will be also explained.

The surface emitting laser array 2000 includes the first surface emitting laser 150, the second surface emitting laser 250, the third surface emitting laser 350, the fourth surface emitting laser 450, and the fifth surface emitting laser 550. The first surface emitting laser 150 is adjacent to the second surface emitting laser 250 and the fourth surface emitting laser 450. The second surface emitting laser 250 is adjacent to the third surface emitting laser 350, and the fourth surface emitting laser 450 is adjacent to the fifth surface emitting laser 550.

The first surface emitting laser 150, the second surface emitting laser 250, the third surface emitting laser 350, the fourth surface emitting laser 450, and the fifth surface emitting laser 550 are formed on the semiconductor substrate 101, and include the second electrode 108 formed on the lower surface of the semiconductor substrate 101, and the first mirror 102 formed on the upper surface of the semiconductor substrate 101. The second electrode 108 and the first mirror 102 can function as an electrode and a mirror that are common to each of the surface emitting lasers.

The first surface emitting laser 150, the second surface emitting laser 250, the third surface emitting laser 350, the fourth surface emitting laser 450, and the fifth surface emitting laser 550 have the same diameters of the columnar portions (shown in numerals 124, 224, 324, 424, and 524) to each other, but different diameters of openings of ion implantation regions as insulation regions (shown in numerals 135, 235, 335, 435, and 535) from each other. Other portions are in the same size and made of the same materials with respect to one another similarly to the surface emitting laser array 1000 described above.

The first surface emitting laser 150 includes the first mirror 102, the active layer 103 formed on the first mirror 102, and the second mirror 104 formed on the active layer 103. The first surface emitting laser 150 is provided with a vertical resonator composed of the first mirror 102, the active layer 103 and the second mirror 104 described above. Further, the first mirror 102, the active layer 103, and a part of the second mirror 104 can constitute the semiconductor deposited body (columnar portion) 124 in a pillar shape. The columnar portion 124 can have, for example, a circular cross section when being cut at a surface parallel to the upper surface of the semiconductor 101. Further, the first surface emitting laser 150 includes the first electrode 109 formed on an upper surface of the second mirror 104.

Explanation about materials of the semiconductor substrate 101, the first mirror 102, the active layer 103, the second mirror 104, the second electrode 108, and the first electrode 109 are omitted since they are the same as those of the surface emitting laser array 1000 according to the first embodiment described above.

The first surface emitting laser 150 includes an ion implantation region 125 formed on at least a part of the second mirror 104. The ion implantation region 125 includes an opening 135 opening in a direction perpendicular to the upper surface of the semiconductor substrate 101. Specifically, the ion implantation region 125 is formed up to at least a lower surface of the second mirror 104 in a depth direction. A cross section when being cut at the surface parallel to the upper surface of the semiconductor substrate 101 can be in a ring shape of a concentric circle with respect to the columnar portion 124. In addition, the ion implantation region 125 can also be formed by being stretched to regions of the active layer 103 and the second mirror 104 in the depth direction. As ions to be injected to the ion implantation region 125, for example, H⁺, B⁺, O⁺, Cr⁺ or the like can be used. By injecting these ions, the ion implantation region 125 can be highly resistible or insulated so as to enable electric current confinement.

The first electrode 109 can be in a ring shape having the opening 119 at the upper surface of the columnar portion 124. At the opening 119, a cross section when being cut at the surface parallel to the upper surface of the semiconductor substrate 101 can be in a circular shape of a concentric circle with respect to a circle in a plane shape of the columnar portion 124. Further, the first electrode 109 has a pad portion for electrically coupling with other elements, a lead portion in a linear shape for coupling the pad portion and the ring shape portion (refer to FIG. 12).

The diameter of the opening 119 of the first electrode 109 is, as shown in FIGS. 10 to 12, smaller than a diameter of the columnar portion 124, and larger than a diameter of the opening 135 of the ion implantation region 125. The diameter of the opening 119 is larger than the diameter of the opening 135 of the ion implantation region 125, preventing light generated between the first mirror 102, the active layer 103, and the second mirror 104 from being blocked by the lower surface of the first electrode 109.

The second surface emitting laser 250 includes, similarly to the first surface emitting laser 150, the first mirror 102, the active layer 203 formed on the first mirror 102, the second mirror 204 formed on the active layer 203. The second surface emitting laser 250 is provided with a vertical resonator composed of the first mirror 102, the active layer 203, and the second mirror 204. Further, the first mirror 102, the active layer 203, and a part of the second mirror 204 can constitute a semiconductor deposited body (columnar portion) 224 in a pillar shape. Materials of the active layer 203 and the second mirror 204 can be the same materials as those of the active layer 103 and the second mirror 104 described above. Therefore, the second mirror 204 of a p-type, the active layer 203 containing no doped impurities, and the first mirror 102 of an n-type constitute a pin diode.

The second surface emitting laser 250 further includes an ion implantation region 225 formed on at least a part of the second mirror 204. Further, the second surface emitting laser 250 includes the first electrode 209 formed on an upper surface of the second mirror 204. By injecting an electric current to the pin diode using the first electrode 209 and the second electrode 108 described above, the first surface emitting laser 150 can be operated.

Materials of the first electrode 209 and the ion implantation region 225 can be also respectively the same materials as those of the first electrode 109 and the ion implantation region 125.

The first electrode 209 can be in a ring shape having the opening 219 at the upper surface of the columnar portion 224. At the opening 219, a cross section when being cut at the surface parallel to the upper surface of the semiconductor substrate 101 can be in a circular shape of a concentric circle with respect to a circle in a plane shape of the columnar portion 224.

The diameter of the opening 219 of the first electrode 209 is, as shown in FIGS. 10 to 12, smaller than a diameter of the columnar portion 224, and larger than a diameter of the opening 235 of the ion implantation region 225.

The third surface emitting laser 350 includes, similarly to the first surface emitting laser 150, the first mirror 102, the active layer 303 formed on the first mirror 102, the second mirror 304 formed on the active layer 303. The third surface emitting laser 350 is provided with a vertical resonator composed of the first mirror 102, the active layer 303, and the second mirror 304. Further, the first mirror 102, the active layer 303, and a part of the second mirror 304 can constitute a semiconductor deposited body (columnar portion) 324 in a pillar shape. Materials of the active layer 303 and the second mirror 304 can be the same materials as those of the active layer 103 and the second mirror 104 described above. Therefore, the second mirror 304 of a p-type, the active layer 303 containing no doped impurities, and the first mirror 102 of an n-type constitute a pin diode.

The third surface emitting laser 350 further includes an ion implantation region 325 formed on at least a part of the second mirror 304. Further, the third surface emitting laser 350 includes the first electrode 309 formed on an upper surface of the second mirror 304. By injecting an electric current to the pin diode using the first electrode 309 and the second electrode 108 described above, the first surface emitting laser 150 can be operated.

Materials of the first electrode 309 and the ion implantation region 325 can be also respectively the same materials as those of the first electrode 109 and the ion implantation region 125.

The first electrode 309 can be in a ring shape having the opening 319 at the upper surface of the columnar portion 324. At the opening 319, a cross section when being cut at the surface parallel to the upper surface of the semiconductor substrate 101 can be in a circular shape of a concentric circle with respect to a circle in a plane shape of the columnar portion 324.

The diameter of the opening 319 of the first electrode 309 is, as shown in FIGS. 10 to 12, smaller than a diameter of the columnar portion 324, and larger than a diameter of the opening 335 of the ion implantation region 325.

The fourth surface emitting laser 450 includes, similarly to the first surface emitting laser 150, the first mirror 102, the active layer 403 formed on the first mirror 102, the second mirror 404 formed on the active layer 403. The fourth surface emitting laser 450 is provided with a vertical resonator composed of the first mirror 102, the active layer 403, and the second mirror 404. Further, the first mirror 102, the active layer 403, and a part of the second mirror 404 can constitute a semiconductor deposited body (columnar portion) 424 in a pillar shape. Materials of the active layer 403 and the second mirror 404 can be the same materials as those of the active layer 103 and the second mirror 104 described above. Therefore, the second mirror 404 of a p-type, the active layer 403 containing no doped impurities, and the first mirror 102 of an n-type constitute a pin diode.

The fourth surface emitting laser 450 further includes an ion implantation region 425 formed on at least a part of the second mirror 404. Further, the fourth surface emitting laser 450 includes the first electrode 409 formed on an upper surface of the second mirror 404. By injecting an electric current to the pin diode using the first electrode 409 and the second electrode 108 described above, the first surface emitting laser 150 can be operated.

Materials of the first electrode 409 and the ion implantation region 425 can be also respectively the same materials as those of the first electrode 109 and the ion implantation region 125.

The first electrode 409 can be in a ring shape having the opening 419 at the upper surface of the columnar portion 424. At the opening 419, a cross section when being cut at the surface parallel to the upper surface of the semiconductor substrate 101 can be in a circular shape of a concentric circle with respect to a circle in a plane shape of the columnar portion 424.

The diameter of the opening 419 of the first electrode 409 is, as shown in FIGS. 10 to 12, smaller than a diameter of the columnar portion 424, and larger than a diameter of the opening 435 of the ion implantation region 425.

The fifth surface emitting laser 550 includes, similarly to the first surface emitting laser 150, the first mirror 102, the active layer 503 formed on the first mirror 102, the second mirror 504 formed on the active layer 503. The fifth surface emitting laser 550 is provided with a vertical resonator composed of the first mirror 102, the active layer 503, and the second mirror 504. Further, the first mirror 102, the active layer 503, and a part of the second mirror 504 can constitute a semiconductor deposited body (columnar portion) 524 in a pillar shape. Materials of the active layer 503 and the second mirror 504 can be the same materials as those of the active layer 103 and the second mirror 104 described above. Therefore, the second mirror 504 of a p-type, the active layer 503 containing no doped impurities, and the first mirror 102 of an n-type constitute a pin diode.

The fifth surface emitting laser 550 further includes an ion implantation region 525 formed on at least a part of the second mirror 504. Further, the fifth surface emitting laser 550 includes the first electrode 509 formed on an upper surface of the second mirror 504. By injecting an electric current to the pin diode using the first electrode 509 and the second electrode 108 described above, the first surface emitting laser 150 can be operated.

Materials of the first electrode 509 and the ion implantation region 525 can be also respectively the same materials as those of the first electrode 109 and the ion implantation region 125.

The first electrode 509 can be in a ring shape having the opening 519 at the upper surface of the columnar portion 524. At the opening 519, a cross section when being cut at the surface parallel to the upper surface of the semiconductor substrate 101 can be in a circular shape of a concentric circle with respect to a circle in a plane shape of the columnar portion 524.

The diameter of the opening 519 of the first electrode 509 is, as shown in FIGS. 10 to 12, smaller than a diameter of the columnar portion 524, and larger than a diameter of the opening 535 of the ion implantation region 525.

Next, the diameters of the columnar portions 124, 224, 324, 424, and 524 will be explained. The diameters of the columnar portions 124, 224, 324, 424, and 524 are formed to be the same as each other as described above, but may be reduced in size from a center toward edges of a region where the plurality of surface emitting lasers 150, 250, 350, 450, and 550 are formed on the semiconductor substrate 101 similarly to the surface emitting laser array 1000 according to the first embodiment.

Next, the diameters of the openings 135, 235, 335, 435, and 535 respectively formed in the ion implantation regions 125, 225, 325, 425, and 525 will be explained. The diameters of the openings 135, 235, 335, 435, and 535 are formed to be reduced in size from the center toward the edges of the region where the plurality of surface emitting lasers 150, 250, 350, 450, and 550 (refer to FIG. 11) are formed on the semiconductor substrate 101. That is, among the openings 135, 235, and 335, the diameter of the opening 135 that is formed in the center is the largest, and then the diameters of the opening 235 and the opening 335 are getting smaller in this order. Further, among the openings 135, 435, and 535, the diameter of the opening 135 that is formed in the center is the largest, and then the diameters of the opening 435 and the opening 535 are getting smaller in this order.

Accordingly, in the surface emitting laser array 2000, by making the diameters of the openings of the oxidized constricting layers smaller from the center toward the edges, temperature differences between the first surface emitting lasers 150, 200, 300, 400, and 500 are made smaller, equalizing optical outputs of the plurality of the surface emitting lasers.

The opening 235 can be either the same, or different from the opening 435. Further, the opening 335 can be either the same, or different from the opening 535. For example, in a case where other elements are formed on the semiconductor substrate 101, if the other elements are formed on the third surface emitting laser 350 side, it is preferable that the diameter of the opening 235 of the ion implantation region 225 be larger than that of the opening 435 of the ion implantation region 425, and the diameter of the opening 335 of the ion implantation region 325 be larger than that of the opening 535 of the ion implantation region 525.

On the other hand, if the other elements are formed on the fifth surface emitting laser 550 side, it is preferable that the diameter of the opening 235 of the ion implantation region 225 be smaller than that of the opening 435 of the ion implantation region 425, and the diameter of the opening 335 of the ion implantation region 325 be smaller than that of the opening 535 of the ion implantation region 505. According to this, the temperatures of the surface emitting lasers 450 and 550 are prevented from partially rising by heat generated from the other elements, maintaining even optical outputs.

The diameters of the openings 119, 219, 319, 419, and 519 respectively formed in the first electrodes 109, 209, 309, 409, and 509 are preferably equal to each other. By equalizing the diameters of the openings 119, 219, 319, 419, and 519, beam diameters can be equalized.

### 2.2.2. Two Dimensional Surface Emitting Laser Array

A surface emitting laser array 2500 provided with a plurality of surface emitting lasers arranged in a two dimension can also have the same features as those of the surface emitting laser array 2000 provided with the plurality of surface emitting lasers arranged in a single dimension. Details are as follows.

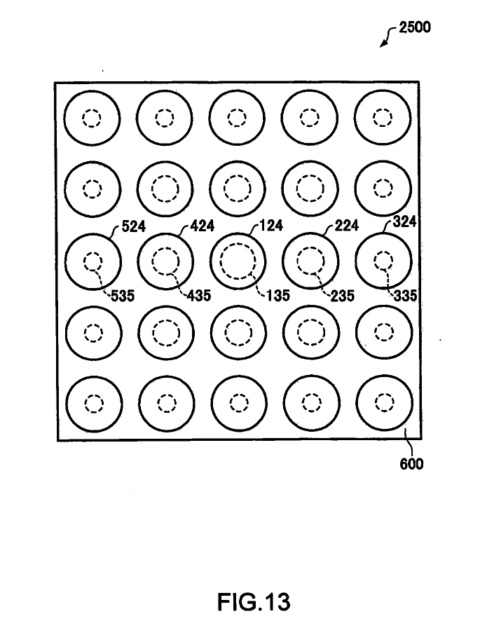

FIG. 13 is a diagram for explaining diameters of columnar portions and openings of ion implantation regions of the surface emitting laser array 2500 according to a modification of the second embodiment.

As shown in FIG. 13, the surface emitting laser array 2500 includes 25 pieces of surface emitting lasers arranged in five rows and five columns. Among these surface emitting lasers, for example, five surface emitting lasers in the third row can have the same configuration and features as those of the first surface emitting laser 150, the second surface emitting laser 250, the third surface emitting laser 350, the fourth surface emitting laser 450, and the fifth surface emitting laser 550. Five surface emitting lasers formed in the third column or in a diagonal line can also have the same configuration and features as those of the first surface emitting laser 150, the second surface emitting laser 250, the third surface emitting laser 350, the fourth surface emitting laser 450, and the fifth surface emitting laser 550.

That is, as shown in FIG. 13, the surface emitting laser array 2500 can also have columnar portions having diameters made to be reduced in size radially from a center toward edges. In this way, temperature differences between the plurality of surface emitting lasers, and further, optical outputs of the plurality of surface emitting lasers can be equalized.

Further, in the surface emitting laser array 2500, diameters of openings of ion implantation regions are reduced in size from the center toward the edges. In this way, temperature differences between the plurality of surface emitting lasers, and further, optical outputs of the plurality of surface emitting lasers can be equalized.

### 2.3. Method for Manufacturing a Surface Emitting Laser Array

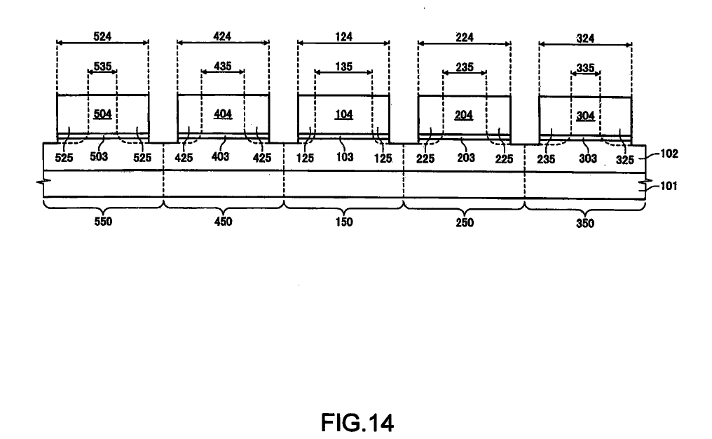

Next, an example of a method for manufacturing the surface emitting laser array 2000 according to the embodiment employing the invention will be explained with reference to FIGS. 10 and 14. FIG. 14 is a sectional view schematically showing a manufacturing step of the surface emitting laser arrays 2000 and 2500 shown in FIGS. 10 to 13, and each corresponds to the sectional view shown in FIG. 1.

(1) First, similarly to the method for manufacturing the surface emitting laser array 1000 according to the first embodiment, the semiconductor multilayered film 150 is formed and patterned. The columnar portions 124, 224, 324, 424, and 524 that have the same diameter with respect to one another are formed by patterning.

(2) Next, by performing an ion implantation from upper sides of the second mirrors 104, 204, 304, 404, and 504, the ion implantation regions 125, 225, 325, 425, and 525 are formed (refer to FIG. 14). The ion implantation can be performed by known ion implantation equipment. As ions to be implanted, for example, H⁺, B⁺, O⁺, Cr⁺, or the like can be used. At this time, the ion implantation is performed after a mask is formed in a predetermined region. The ion implantation regions 125, 225, 325, 425, and 525 are formed in regions other than the region where the mask is formed. As described above, the diameters of the openings 135, 235, 335, 435, and 535 are reduced in size from the center toward the edges of the region where the plurality of surface emitting lasers 150, 250, 350, 450, and 550 (refer to FIG. 10) are formed on the semiconductor substrate 101.

(3) Next, similarly to the method for manufacturing the surface emitting laser array 1000 according to the first embodiment, the insulation layer 600, the first electrode 109, and the second electrode 108 are formed.

According to the steps above, as shown in FIG. 10, the surface emitting laser array 2000 or the surface emitting laser array 2500 is obtained.

### 3. Third Embodiment

### 3.1. Method for Manufacturing a Surface Emitting Laser Array

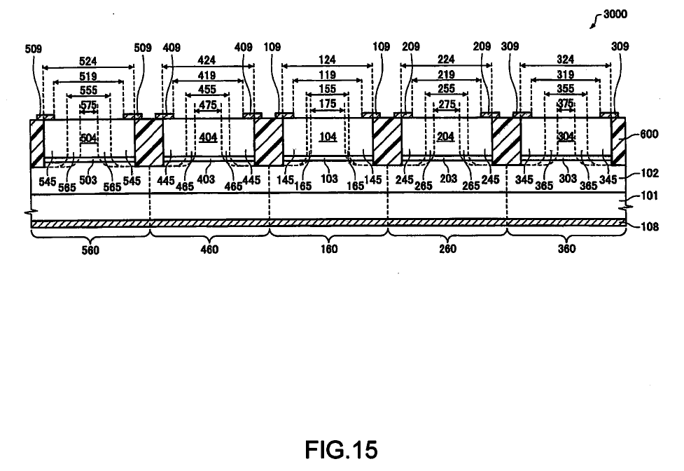

Next, a surface emitting laser array 3000 according to a third embodiment will be explained. FIG. 15 is a sectional view schematically showing the surface emitting laser array 3000 according to the third embodiment.

A method for manufacturing the surface emitting laser array 3000 according to the third embodiment differs in that an insulation region is added after the first electrode 109 is formed from the methods for manufacturing the surface emitting laser arrays according to the first embodiment and the second embodiment. The insulation region is added by an ion implantation. After the first electrode 109 is formed, a region to add the insulation region is determined. By performing an ion implantation to the determined region, the surface emitting laser array 3000 can be manufactured. A detailed manufacturing method is as follows.

(1) First, similarly to the method for manufacturing the surface emitting laser array 1000 according to the first embodiment, the semiconductor multilayered film 150 is formed and patterned. The columnar portions 124, 224, 324, 424, and 524 that have the same diameter with respect to one another are formed by patterning.

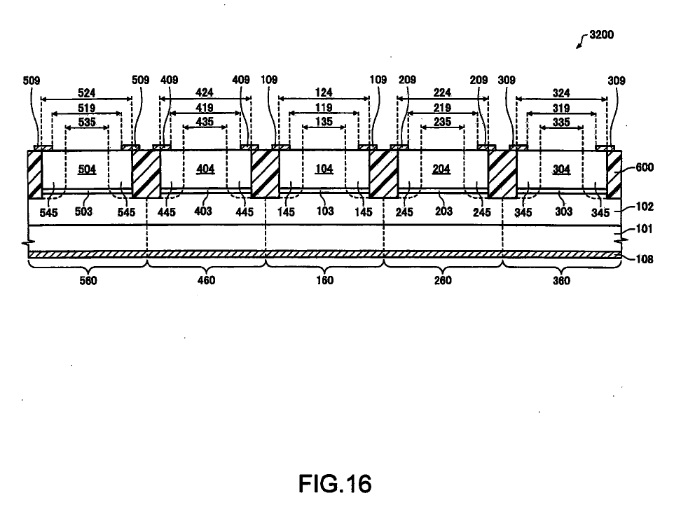

(2) Next, by performing an ion implantation from upper sides of the second mirrors 104, 204, 304, 404, and 504, the ion implantation regions 145, 245, 345, 445, and 545 are formed (refer to FIG. 16). The ion implantation can be performed by known ion implantation equipment. As ions to be injected, for example, H⁺, B⁺, O⁺, Cr⁺, or the like can be used. At this time, the ion implantation is performed after a mask is formed in a predetermined region. The ion implantation regions 145, 245, 345, 445, and 545 are formed in regions other than the region where the mask is formed. Diameters of openings 155, 255, 355, 455, and 555 can be either equal to or different from each other.

(3) Next, similarly to the method for manufacturing the surface emitting laser array 1000 according to the first embodiment, the insulation layer 600, the first electrode 109, and the second electrode 108 are formed. According to the steps above, a surface emitting laser array 3200 is formed. FIG. 16 is a sectional view schematically showing the surface emitting laser array 3200.

(4) Next, while an electric current is injected to each of surface emitting lasers 160, 260, 360, 460, and 560, a temperature of each of the surface emitting lasers is measured. It is preferable to measure the temperature around the active layer 103.

(5) Next, based on the measured temperature of each of the surface emitting lasers, a region to add the insulation region is determined, and then an ion implantation is performed to the determined region as shown below, for example.

First, the highest temperature among the measured temperatures of the surface emitting lasers is regarded as a reference temperature. Corresponding to difference from the reference temperature, the region (an additional ion implantation region) to add the insulation region is determined. For example, a surface emitting laser having a larger difference from the reference temperature needs to have a larger additional ion implantation region.

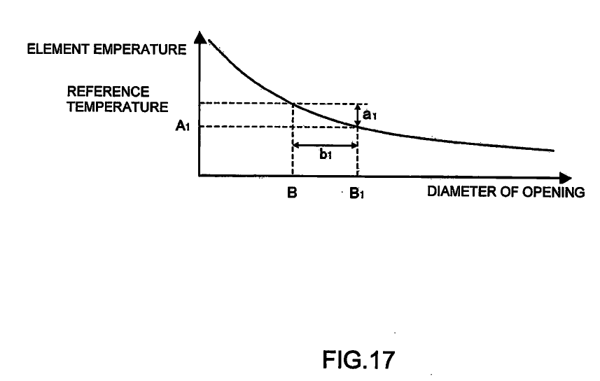

More specifically, a graph as shown in FIG. 17 can be made by each surface emitting laser (by each position on the semiconductor substrate 101). Based on the graph, the additional ion implantation region may be determined. FIG. 17 is a diagram showing a temperature of a surface emitting laser corresponding to a diameter of an opening of an insulation region (ion implantation region). In FIG. 17, a horizontal axis indicates a diameter of an opening of an insulation region (ion implantation region) while a vertical axis indicates a temperature of a surface emitting laser. For example, if a difference between a temperature A₁ measured in step (4) for the surface emitting laser 160 and a reference temperature is a₁, an additional ion implantation region 165 is formed so as to have a diameter B by making a diameter B₁ of an opening of the ion implantation region small by b₁. In FIG. 15, a difference between a diameter of the opening 155 of the ion implantation region 145 and a diameter of the opening 175 of the additional ion implantation region 165 corresponds to b₁.

Accordingly, forming an additional ion implantation region is also performed to other surface emitting lasers 260, 360, 460, and 560, allowing additional ion implantation regions 265, 365, 465, and 565 to be formed, so that openings 275, 375, 475, and 575 are formed.

Through the above steps, the surface emitting laser array 3000 according to the third embodiment can be manufactured. In this way, since the additional ion implantation region is formed after the electrode is formed and followed by a temperature measurement of the surface emitting laser, even when the temperature is changed due to not only positions on the semiconductor substrate 101, but also influence of various factors on the surface emitting lasers, optical outputs of the plurality of surface emitting lasers in the surface emitting laser array 3000 can be equalized with high accuracy.

### 4. Semiconductor Device (Fourth Embodiment)

Next, a semiconductor device that can employ the surface emitting laser array described above will be described.

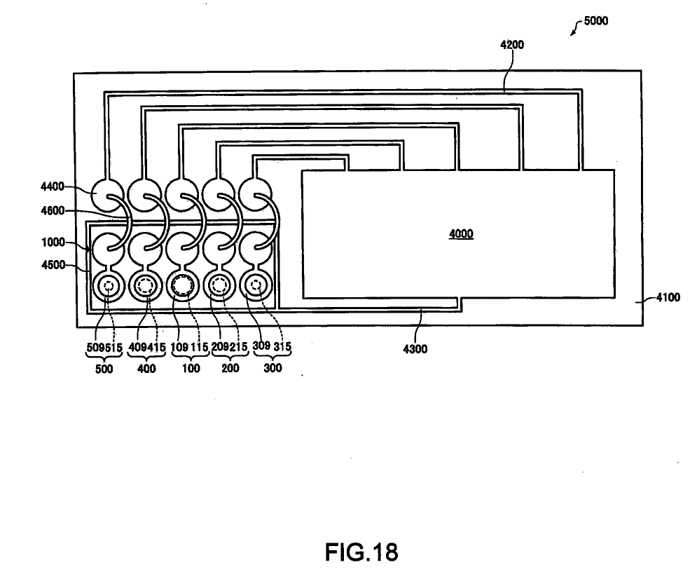

FIG. 18 is a plan view schematically showing a semiconductor device 5000 according to a fourth embodiment. The semiconductor device 5000 according to the fourth embodiment includes the surface emitting laser array 1000 according to the first embodiment, a drive circuit 4000 for operating a plurality of surface emitting lasers included in the surface emitting laser array 1000, a substrate 4100 for supporting the drive circuit 4000 and the surface emitting laser array 1000, wiring portions 4200 and 4300 for electrically coupling the drive circuit 4000 with the surface emitting laser array 1000, and pad portions 4400 and 4500.

The drive circuit 4000 is electrically coupled with the first electrode 109 through the wiring portion 4200 and the pad portion 4400. The first electrode 109 is coupled with the pad portion 4400 by a wire 4600, for example. Further, the drive circuit 4000 is electrically coupled with the second electrode 108 through the wiring portion 4300 and the pad portion 4500. The second electrode 108 is formed on a lower surface of the surface emitting laser array 1000, thereby being coupled through neither the pad portion 4500 formed on an upper surface of the substrate 4100 nor wiring. In the fourth embodiment, the plurality of the surface emitting lasers are supported by the substrate 4100 via the semiconductor substrate 101 (refer to FIG. 1) and the pad portion 4500, however, can be directly formed on the substrate 4100 to be supported. That is, the semiconductor substrate 101 described above and the substrate 4100 may be the same substrate.

In the semiconductor device 5000 having such a configuration as above, the surface emitting laser array 1000 may be affected by heat generated at the drive circuit 4000 because of being arranged in a position adjacent to the drive circuit 4000. Therefore, the diameters of the columnar portions 214 and 314 of the surface emitting lasers 200 and 300 that are arranged in a drive circuit 4000 side (refer to FIG. 1) and the diameters of the openings 215 and 315 of the oxidized constricting layers 205 and 305 can be made to be larger than those of the surface emitting laser array 1000 according to the first embodiment.

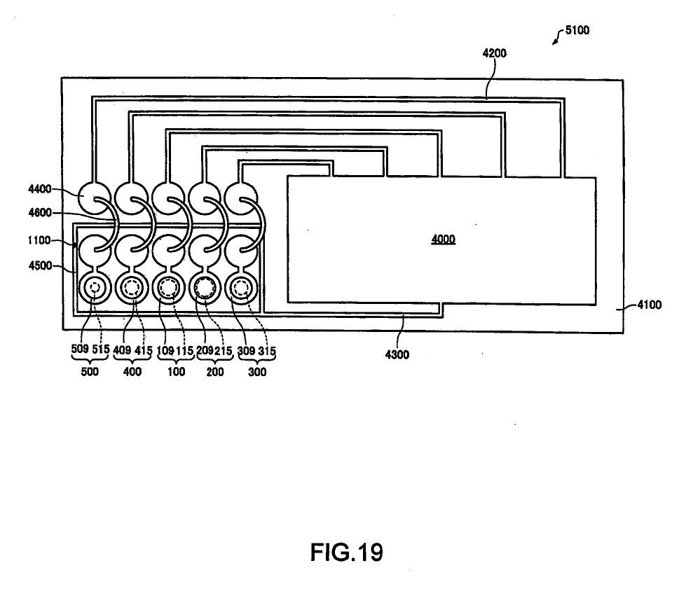

That is, in a surface emitting laser array 1100 of the semiconductor device 5100 that can avoid influence of heat from a drive circuit, diameters of columnar portions and openings of oxidized constricting layers respectively included in the plurality of surface emitting lasers are reduced in size from a predetermined position toward edges on the substrate. However, the predetermined position is located not in the center of the plurality of surface emitting lasers similar to the surface emitting laser array 1000 described above, but in a position closer to the drive circuit 4000 side from the center of a region where only the plurality of surface emitting lasers are formed. An example of a semiconductor device that can avoid influence of heat from a drive circuit is shown in FIG. 19.

FIG. 19 is a plan view schematically showing an example of the semiconductor device 5100 that can avoid influence of heat from a drive circuit. In the surface emitting laser array 1100, the diameters of the columnar portions 214 and 314 of the surface emitting lasers 200 and 300 that are arranged in the drive circuit 4000 side and the diameters of the openings 215 and 315 of the oxidized constricting layers 205 and 305 can be made to be larger than those of the surface emitting laser array 1000 according to the first embodiment, thereby suppressing increase of an element temperature due to heat from the drive circuit 4000, and further preventing optical outputs from degrading.

The semiconductor device that can avoid influence of heat from a drive circuit as shown in FIG. 19 can employ not only the surface emitting laser array 1000, but also the surface emitting laser array 1500, 2000, 2500, or 3000 by adjusting the diameters of the openings of the ion implantation regions and the columnar portions.

As understood by those skilled in the art, various changes can be made with the embodiment of the invention that has been described in detail as above without substantially departing from new matters and advantages of this invention. Therefore, it is to be noted that these modifications are all included in the scope of the invention.

Further, the surface emitting laser array according to the embodiment described above can be applied to laser printers, projectors, medical apparatuses for treatment, equipment for tests such as sensors, and the like. The surface emitting laser array according to the embodiment of the invention is highly reliable as it has an equalized output characteristic, thereby being favorably applied to various applications.

What is claimed is:

1. A surface emitting laser array, comprising:
a plurality of surface emitting lasers aligned on a same substrate, the plurality of surface emitting lasers including:
a first surface emitting laser;
a second surface emitting laser adjacent to the first surface emitting laser; and
a third surface emitting laser adjacent to the second surface emitting laser, each of the plurality of surface emitting lasers being operated by an independent signal with respect to one another and including:
a first mirror formed on an upper side of the substrate;
an active layer formed on an upper side of the first mirror;
a second mirror formed on an upper side of the active layer; and
a columnar portion composed of at least the second mirror and the active layer, wherein a diameter of the columnar portion of the second surface emitting laser is smaller than a diameter of the columnar portion of the first surface emitting laser, and larger than a diameter of the columnar portion of the third surface emitting laser.

2. The surface emitting laser array according to claim 1, wherein the first surface emitting laser, the second surface emitting laser, and the third surface emitting laser are aligned in a straight line.

3. The surface emitting laser array according to claim 1, wherein the diameters of the columnar portions respectively included in the plurality of surface emitting lasers are reduced in size from a center toward an edge portion of a region in which the plurality of surface emitting lasers are formed on the substrate.

4. The surface emitting laser array according to claim 1, wherein the first surface emitting laser, the second surface emitting laser, and the third surface emitting laser are formed on an upper side of the second mirror, and further include an electrode having an opening portion for emitting laser light, the opening portion of the electrode included in the first surface emitting laser having a diameter that is equal to a diameter of the opening portion of the electrode included in the second surface emitting laser and a diameter of the opening portion of the electrode included in the third surface emitting laser.

5. A surface emitting laser array, comprising:
a plurality of surface emitting lasers aligned on a same substrate, the plurality of surface emitting lasers including:
a first surface emitting laser;
a second surface emitting laser adjacent to the first surface emitting laser; and
a third surface emitting laser adjacent to the second surface emitting laser, each of the plurality of surface emitting lasers being operated by an independent signal with respect to one another and including:
a first mirror formed on an upper side of the substrate;
an active layer formed on an upper side of the first mirror;
a second mirror formed on an upper side of the active layer; and
an insulation region at least formed in a part of a region of the second mirror and including an opening portion opening in a direction perpendicular to a surface of the substrate, wherein a diameter of the opening portion of the second surface emitting laser is smaller than a diameter of the opening portion of the first surface emitting laser, and larger than a diameter of the opening portion of the third surface emitting laser.

6. The surface emitting laser array according to claim 5, wherein the first surface emitting laser, the second surface emitting laser, and the third surface emitting laser are aligned in a straight line.

7. The surface emitting laser array according to claim 5, wherein the diameters of the opening portions of the insulation regions respectively included in the plurality of surface emitting lasers are reduced in size from a center toward an edge portion of a region in which the plurality of surface emitting lasers are formed on the substrate.

8. The surface emitting laser array according to claim 5, wherein the first surface emitting laser, the second surface emitting laser, and the third surface emitting laser are formed on an upper side of the second mirror and further include an electrode having an opening portion for emitting laser light, the opening portion of the electrode included in the first surface emitting laser having a diameter that is equal to a diameter of the opening portion of the electrode included in the second surface emitting laser and a diameter of the opening portion of the electrode included in the third surface emitting laser.

9. The surface emitting laser array according to claim 5, wherein the insulation region is an oxidized constricting layer formed by oxidizing a part of the second mirror.

10. The surface emitting laser array according to claim 5, wherein the insulation region is an ion implantation region formed by injecting an ion to a part of the second mirror.

11. A semiconductor device, comprising:
a substrate;
a surface emitting laser array including a plurality of surface emitting lasers formed on the substrate;
a drive circuit formed on the substrate and electrically coupled with the plurality of surface emitting lasers, each of the plurality of surface emitting lasers being operated by an independent signal with respect to one another and including:
a first mirror formed on an upper side of the substrate;
an active layer formed on an upper side of the first mirror;
a second mirror formed on an upper side of the active layer; and
a columnar portion composed of at least the second mirror and the active layer, wherein diameters of the columnar portions respectively included in the plurality of surface emitting lasers are reduced in size from a predetermined position toward an edge portion on the substrate, and the predetermined position is in a position closer to a drive circuit side from a center of a region where only the plurality of surface emitting lasers are formed.

12. A semiconductor device, comprising:
a substrate;
a surface emitting laser array including a plurality of surface emitting lasers formed on the substrate;
a drive circuit formed on the substrate and electrically coupled with the plurality of surface emitting lasers, each of the plurality of surface emitting lasers being operated by an independent signal with respect to one another and including:
a first mirror formed on an upper side of the substrate;
an active layer formed on an upper side of the first mirror;
a second mirror formed on an upper side of the active layer; and
an insulation region at least formed in a part of a region of the second mirror and including an opening portion opening in a direction perpendicular to a surface of the substrate, wherein the diameters of the opening portions of the insulation regions respectively included in the plurality of surface emitting lasers are reduced in size from a predetermined position toward an edge portion on the substrate, and the predetermined position is in a position closer to a drive circuit side from a center of a region where only the plurality of surface emitting lasers are formed.

13. A method for manufacturing a surface emitting laser array including a plurality of surface emitting lasers aligned on a same substrate, comprising:
(a) forming a semiconductor multilayered film for composing a first mirror, an active layer, and a second mirror from a substrate side on an upper side of the substrate;
(b) forming an insulation region having an opening portion by injecting an ion in a predetermined region from an upper side of the semiconductor multilayered film;
(c) forming a plurality of electrodes having an opening portion composing a light emitting surface in an upper side of the insulation region; and
(d) expanding the insulation region by injecting an ion in the opening portion of the insulation region through the opening portion of the electrode.

14. The method for manufacturing a surface emitting laser array according to claim 13, further comprising measuring a temperature of the semiconductor multilayered film while an electric current is injected to each of the electrodes after step (c), wherein a region to inject the ion in the semiconductor multilayered film is determined based on the measured temperature, and the ion is injected to the determined region in step (d).

15. The method for manufacturing a surface emitting laser array according to claim 13, wherein the opening portion of the insulation region formed in step (b) is formed in an inner side of the opening portion of the electrode.

16. The method for manufacturing a surface emitting laser array according to claim 13, wherein diameters of the opening portions of the insulation regions are reduced in size from a center toward an edge portion of a region in which the plurality of surface emitting lasers are formed on the substrate.
